(19) United States
(12) Patent Application Publication
(10) Pub. No.: US 2007/0298158 A1
(43) Pub. Date: Dec. 27, 2007

(54) Testing bonding materials in a disc production line

(76) Inventors: Marion Keith Martin, Thousand Oaks, CA (US); Bang Thai Dinh, Simi Valley, CA (US); Justin John Cunningham, Westlake Village, CA (US)

Correspondence Address: THOMSON LICENSING LLC, Two Independence Way, Suite 200, PRINCETON, NJ, 08540, US

(21) Appl. No.: 11/473,881

(22) Filed: Jun. 23, 2006

(51) Int. Cl. B05C 11/02; B05B 1/28; B05C 11/00; C23C 16/52

(52) U.S. Cl. 427/8; 118/52; 118/56; 118/326; 118/319; 118/320; 427/240; 118/684; 427/345

(57) ABSTRACT

An apparatus for introducing a testing material into an optical disc production includes a vessel for holding a test material and a regulator for pressurizing the vessel, wherein the vessel and regulator are connectable to a disc production for using the test material in lieu of bonding material in the disc production.

### FIELD OF THE INVENTION

The present invention generally relates to optical disc production, and, more particularly, to a system and method for introducing and using a test material into an optical disc production line in an efficient manner which limits waste.

### BACKGROUND OF THE INVENTION

During optical disc production, namely digital video disc (DVD) production, bonding via lacquers or resins is a necessary step, as DVD discs comprise multiple substrates. A variety of bonding materials (e.g., acrylic resins) may be available for use in the bonding step, e.g., from different manufacturers, and may comprise different formulas. At times, a disc manufacturer may desire to switch to a different type of bonding material due to cost and/or quality concerns, etc. New bonding materials must be tested to ensure that the resultant discs meet requisite quality parameters, so as to perform properly (e.g., be playable).

When using a new material, a test disc needs to be produced and then subjected to testing over a period of time (e.g., several days) to evaluate the performance of the disc and the new bonding material. However, different bonding materials are often not compatible with each other, and thus must not be intermingled during production. To produce a test disc using a different or “test” bonding material, a disc replication line must be taken out of production, the existing material purged, and the test material supplied into the line. Test discs must be made for all types of production line configurations and for each different type of bonding resin. Upon production of a test disc, it may be desirable to return the line to its original condition and put back into production using the original “existing” bonding material. Typically, in existing disc production lines, the introduction of a new bonding material (“test material”) requires a time-consuming series of steps; namely:
a. drain the system of the original bonding material (which must typically be treated as e.g., hazardous waste)
b. replace the filter and refill with the test material;
c. create test discs (usually 100-200 test discs needed)
d. drain the system of the test material (e.g., typically also hazardous waste)
e. replace with another new filter and refill the original material

This presents a number of major disadvantages, in that the existing bonding material (lacquer) in the system is wasted (moreover, it has to be handled and disposed of as hazardous material), at least two filters are used, and the line is taken out of production for an extended length of time, at least 6 hours or more.

### SUMMARY OF THE INVENTION

The present invention provides a system and method that allows for the introduction and use of a test bonding material in an optical disc, e.g., a DVD disc, production line that would enable a sample disc(s) to be produced with improved efficiency, minimal impact on the production capability of the line, and reduced material waste.

According to one aspect, an apparatus for introducing a testing material into an optical disc production includes a vessel for holding a test material and a regulator for pressurizing the vessel, wherein the vessel and regulator are connectable to a disc production for using the test material in lieu of bonding material in the disc production.

According to another aspect of the present invention, a method includes the steps of directing a bonding material in a disc production for use after testing and dispensing a testing material for use in the disc production. The method further includes returning the directed bonding material to the disc production after the testing material is removed from the disc production.

According to yet another aspect, a test assembly for a disc production includes a vessel having a feed valve and for holding a test material, a regulator for pressurizing the vessel, a control valve for being pressurized by the regulator, and a dosing valve for being connected to the control valve and for receiving and dispensing a test material from the feed valve. In a preferred embodiment, the assembly includes an applicator for receiving the test material and dispensing the test material into a bowl, and a waste tank for collecting waste from the bowl.

### BRIEF DESCRIPTION OF THE DRAWINGS

The advantages, nature, and various additional features of the invention will appear more fully upon consideration of the illustrative embodiments now to be described in detail in connection with accompanying drawings wherein:

FIG. 1 is schematic diagram of exemplary test systems and setups for use in accordance with embodiments of the present invention;

FIG. 2 is a flow diagram of an exemplary method of introducing a test bonding material into an optical disc pump dispense line according to an embodiment of the present invention;

FIG. 3 is a flow diagram of an exemplary method of introducing a test bonding material into an optical disc pressure dispense line according to an embodiment of the present invention;

FIG. 4 is a flow diagram of an exemplary method of returning to an original bonding material in an optical disc pump dispense line according to an embodiment of the present invention; and

FIG. 5 is a schematic diagram of an exemplary pump dispense system setup during use of a test system according to the present invention with an existing pump dispense system.

It should be understood that the drawings are for purposes of illustrating the concepts of the invention and are not necessarily the only possible configuration for illustrating the invention.

### DETAILED DESCRIPTION OF THE INVENTION

Aspects of the present invention provide a system, apparatus and method which enable the introduction of a new (“test”) bonding material (e.g., acrylic resin/lacquer) in an optical disc manufacturing production line, e.g., a Digital Video Disc (DVD) disc production line, with maximum efficiency and minimum waste. Advantageously, a system according to the present invention is easily installable on existing DVD production lines, prevents the need to replace filters and minimizes the time that the line is out of production.

It is to be understood that the present invention is particularly applicable to DVD disc manufacturing lines, but however may be used with any disc production system including CD, video discs or any other injection molded media that utilizes a production cycle which includes disc bonding materials (e.g., acrylic resins/lacquers, etc.) for bonding together e.g. metallized polycarbonate layers.

It should be understood that the elements shown in the FIGS. may be implemented in various forms of hardware, software or combinations thereof. Preferably, these elements are implemented in a combination of hardware and software on one or more appropriately programmed general-purpose devices, which may include a processor, memory and input/output interfaces. It is noted that the method steps shown are in an exemplary sequence for illustrative purposes, and the steps are not necessarily required to be performed in the order shown.

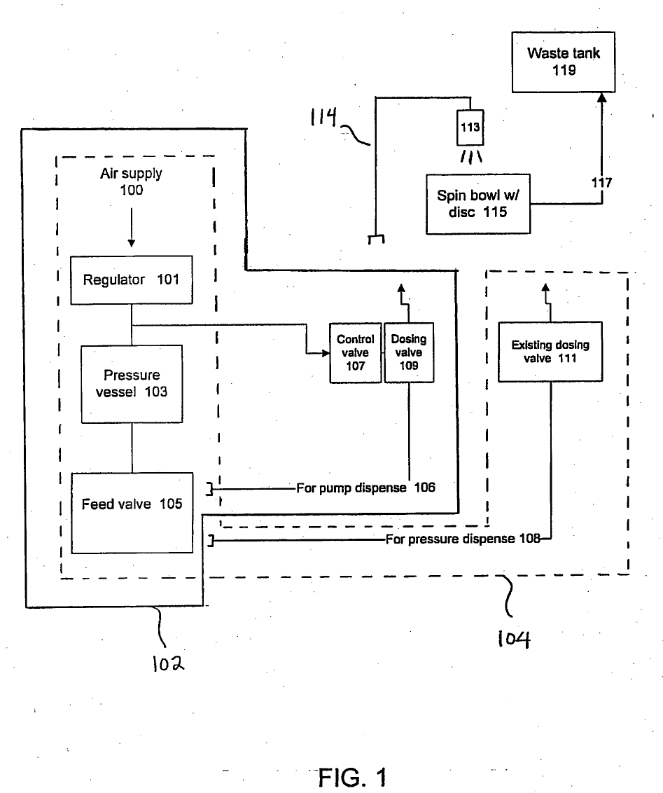

Referring now in specific detail to the drawings in which like reference numerals identify similar or identical elements throughout the several views, and initially to FIG. 1, a schematic diagram illustratively shows a system and exemplary setups for a pump dispense 106 and a pressure dispense system 108 according to the present invention. Details of the individual block components making up the system architecture are known to skilled artisans, and will only be described in details sufficient for an understanding of the present invention.

According to one aspect, a test assembly is provided, comprising a pressure vessel 103 for holding, e.g., a bonding material to be tested. In one exemplary embodiment, the vessel 103 is adapted to hold about 2 kilograms of test material. Test materials may comprise e.g., various acrylic resins or lacquer formulations, readily determinable by one of skill in the art, which may be utilized in bonding processes in optical disc (e.g., DVD) manufacturing. A pressure regulator 101 is provided which receives an air supply 100 for controlling air pressure in pressure vessel 103 as well as a control valve 107. The control valve 107 comprises a pneumatically controlled dispense valve, which utilizes compressed air to control the dispensing of resin from the dosing valve. The vessel 103 includes a feed valve 105, which may comprise, e.g., a manual valve located at a bottom of the vessel 103.

A test assembly according to the present invention may be utilized in existing optical disc production lines, e.g., a pump dispense system 106 or a pressure dispense system 108. When connected to a pump dispense system. 106, the test assembly comprises components in block 102 (e.g., components 101, 103, 105,107 and 109). Valve 109 may replace the existing OEM (original equipment manufacturer) dosing valve (not shown) in the existing pump dispense system.

When connected to a pressure dispense system 108, the test assembly comprises components in block 104 indicated in broken lines (i.e., components 101, 103 and 105, connected to an existing dosing valve 111 in the pressure dispense system).

Once the test assembly is connected to either a pump or pressure dispense system, the test material may be dispensed via dosing valves 109 or 111 to a system resin applicator (e.g., a “lacquer needle”) 113 for applying the resin to a disc in an applicator bowl 115 (e.g., a spin bowl); In either pump or pressure dispense systems, a test assembly includes a drain line 117 routed to a waste container 119 to collect the, e.g., spin-off waste when a test material is being used to prevent the test material from contaminating the original production line and the original bonding material.

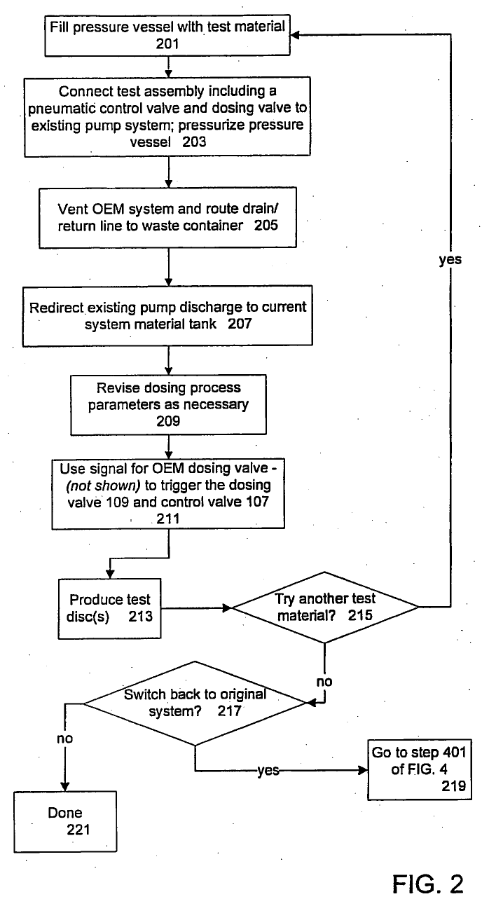

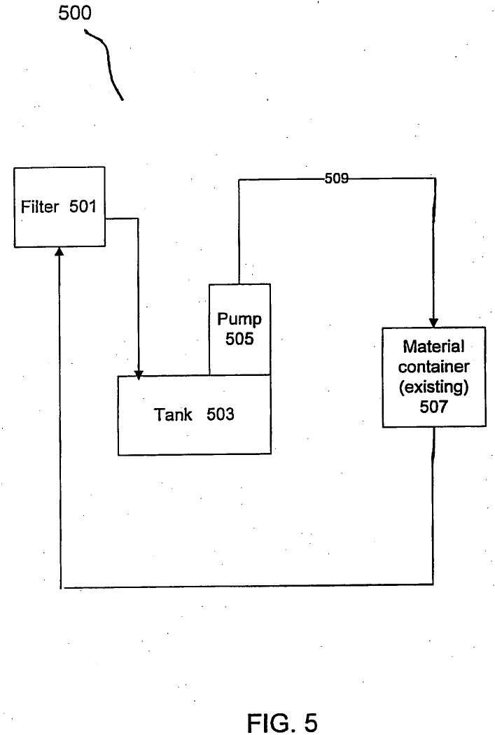

FIG. 2 illustrates an exemplary method flow for testing a new bonding material in a pump dispense optical disc manufacturing line according to an aspect of the present invention. FIG. 5 depicts an exemplary setup of a pump dispense system during use of a test assembly in a pump dispense line according to an aspect of the present invention. In step 201, a test assembly is provided including a pressure vessel filled with the desired amount/type of test material (resin). The test assembly further includes a pressure regulator, a feed valve connected to the pressure vessel, and a pneumatically operated control valve which is operably connected to a dosing valve.

According to another aspect, the existing production system (here, a pump dispense system) is intercepted (e.g., at hose 114 between the existing pump and the resin applicator needle) and the test assembly is connected thereto (e.g., the dosing valve 109 is connected to the applicator needle 113 via hose 114). The vessel and the control valve are pressurized (step 203). The existing (OEM) system is vented, e.g., by removing the existing system pressure connection, and a drain/return line (e.g., line 117) is routed from the applicator/spin bowl (holding a disc to be coated) to a waste tank (step 205). Preferably, the line 114 is flushed before and after use to prevent, e.g., material cross-contamination. The use of drain line 117 to a separate waste tank enables separate collection of the spin-off and purged test material and thus prevents inter-mixing and contamination of different bonding materials.

In step 207, the discharge line of the existing pump 505 (e.g., as shown in FIG. 5) is disconnected and a return line 509 is connected to the pump 505 to re-direct the pump discharge to the existing material tank 507 of the system. Thus, during the use of a test assembly of the present invention, the existing pump system is enabled to continue to operate normally, with its existing bonding material simply being returned to its source tank via, e.g., a temporary hose. This allows the pump 505 to continue to run and cycle material back into the OEM system. Advantageously, this prevents the system from becoming air-bound and thus prevents having to prime the pump when the existing original pump system is re-connected.

The dosing process (e.g., application of the proper thickness of bonding material on a disc) may need to be revised as necessary depending on the type of test material used and its particular attributes, e.g., its viscosity, etc. (step 209). For example, typically, a layer of bonding material about 40-60 microns thick is desirable on a DVD disc, and necessary alterations to the dosing may be done in accordance with the type of test bonding material used, so as to achieve the proper thickness during application.

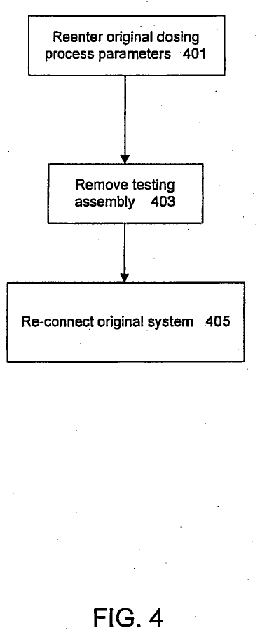

The signal communicating the dispense command for the existing OEM dosing valve (not shown) may be used to trigger the control valve (e.g., 107) and dosing valve (e.g., 109) in a test assembly according to the present invention to dispense the test lacquer (step 211). The test material is dispensed from the dosing valve (e.g., 109) to the system applicator (e.g., needle 113) for application onto a disc (e.g., in bowl 115), and the desired number of test discs using the test material is produced accordingly (step 213). In step 215, it is ascertained whether a new test bonding material is desired to be used; if yes, the process returns to step 201 using the new bonding material, if no, in decision block 217 it is determined if it is desired to switch back to the existing original production system. If yes, the process proceeds to step 401 of FIG. 4 (step 219); if no, the process is done (step 221).

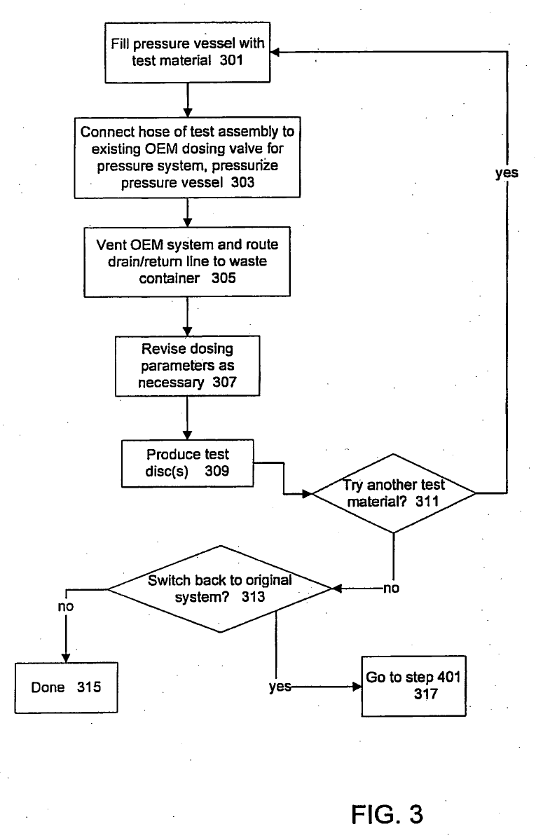

FIG. 3 is a flow diagram of an exemplary method of introducing a test bonding material into an optical disc pressure dispense line according to an embodiment of the present invention. In this example, a vessel is filled with the test material desired to be tested (step 301). The vessel (e.g., via the feed valve) is connected directly to the existing (OEM) dosing valve via a connecting hose 108 and the vessel is pressurized; the existing dosing valve (e.g., 111) is connected to line 114, for enabling dispensing of the test material via applicator 113 onto the bowl 115 (step 303).

The existing system is vented and a drain/return line is routed from the spin bowl to a separate waste container to collect any spin-off waste and prevent, e.g., material cross-contamination (step 305). Dosing parameters may be adjusted/revised as needed (step 307), depending on the type of test material being used in the system, to achieve the desired thickness and coating of the test bonding material onto a disc.

Test disc(s) may be accordingly produced with the modified system (step 309). In decision block 311, it is ascertained if another type of test material is desired to be tested; if yes, the process returns to step 301 using e.g., the new test material. If no, in decision block 313 it is determined whether it is desired to switch back to the original system. If yes, the process proceeds to step 401 of FIG. 4, if no the process is done (step 315).

FIG. 4 illustrates an exemplary process for returning a production line to utilizing its original (prior) bonding material. The process of FIG. 4 is applicable to either pump or pressure dispense systems. In step 401, the dosing parameters suited for the original bonding material are re-entered into the system, the testing assembly according to the present invention is removed (step 403) and the original system is re-connected accordingly to its original configuration (step 405).

Advantageously, the present invention enables the original disc production system to immediately return to production using the prior bonding material, without the need for draining, cleaning or replacing the filter of the existing resin system. Further, the virtually immediate switching between use of different bonding materials with ease and efficiency is facilitated, thus saving money, time and preventing waste, and in particular, reducing the amount of hazardous material required to be disposed of.

FIG. 5 is a schematic diagram of an exemplary pump dispense system setup 500 during connection of a test system according to the present invention with a conventional pump dispense system. Typical pump dispense systems include a filter 501 for screening bonding material (resin) from a container 507. The filtered material is input to a tank 503 to which a pump 505 is connected for dispensing the bonding material. Here, the line from pump is disconnected (e.g., during connection of the test assembly of the present invention), and a temporary hose 509 is used to direct the pump discharge to the container 507. Thus, during the process of attaching a test assembly to a pump dispense system, the existing pump system is enabled to continue to operate normally, with the bonding material being returned to the source container 507 via an added hose. This prevents the need for priming (“blowing air out of”) the pump when the original existing pump system is re-connected.

Having described preferred embodiments for system and method for testing bonding materials in optical disc production lines (which are intended to be illustrative and not limiting), it is noted that modifications and variations can be made by persons skilled in the art in light of the above teachings. It is therefore to be understood that changes may be made in the particular embodiments of the invention disclosed which are within the scope and spirit of the invention as outlined by the appended claims. Having thus described the invention with the details and particularity required by the patent laws, what is claimed and desired protected by Letters Patent is set forth in the appended claims.

What is claimed is:

1. An apparatus comprising:
a vessel (103) for holding a test material,; and
a regulator (101) for pressurizing the vessel, wherein the vessel and regulator are connectable to a disc production for using the test material.

2. The apparatus according to claim 1, wherein the vessel and regulator are connectable to a disc production for using the test material in lieu of bonding material in the disc production.

3. The apparatus according to claim 1, wherein the existing disc production system comprises a pressure dispenser.

4. The apparatus according to claim 2, wherein the vessel includes a feed valve (105) and further comprising:
a dosing valve (109) for connecting to the feed valve for dispensing the test material; and
a control valve (107) for regulating discharge of the test material from the dosing valve (109), control valve (107) being pressurized regulator (101).

5. The assembly according to claim 1, further comprising:
an applicator (113) for receiving the test material and dispensing the test material into an applicator bowl (115); and
a waste tank (119) connected to the applicator bowl (115) to collect waste.

6. A method comprising the steps of:
directing (207) a bonding material in a disc production for use after testing; and
dispensing a testing material for use in the disc production.

7. The method of claim 6, further comprising the step of returning the directed bonding material to the disc production after the testing material is removed from the disc production.

8. The method of claim 6, wherein the step of dispensing comprises controlling dosing of the test material into the disc production.

9. The method of claim 6, wherein the step of dispensing comprises adjusting a dose of the test material responsive to characteristics of the test material.

10. The method of claim 6, wherein the step of dispensing comprises determining changes in dosing of the test material.

11. The method of claim 6, wherein the step of dispensing comprises determining test material characteristics required.

12. A test assembly for disc production, comprising:
a vessel (103) including a feed valve and for holding a test material;
a regulator (101) for pressurizing the vessel;
a control valve (107) for being pressurized by the regulator; and
a dosing valve (109) for being connected to the control valve and for receiving and dispensing a test material from the feed valve.

13. The assembly of claim 12, further comprising:
an applicator (113) for receiving the test material and dispensing the test material into a bowl; and
a waste tank (119) for collecting waste from the bowl.

14. The assembly of claim 12, further comprising a return line (509) for routing material in a pump dispense of the disc production to a material source tank (507) in the pump dispense.
